(19) United States
(12) Patent Application Publication
(10) Pub. No.: US 2024/0333028 A1
(43) Pub. Date: Oct. 3, 2024

(54) ACOUSTIC ENERGY HARVESTING USING RESONATORS

(71) Applicant: Toyota Motor Engineering & Manufacturing North America, Inc., Plano, TX (US)

(72) Inventors: Taehwa Lee, Ann Arbor, MI (US); Xiaopeng Li, Ann Arbor, MI (US); Ziqi Yu, Ann Arbor, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/192,088

(22) Filed: Mar. 29, 2023

(51) Int. Cl. H02J 50/00; H03H 9/205

(52) U.S. Cl. CPC H02J 50/001; H03H 9/205

(57) ABSTRACT

A system can be configured to harvest energy from sound waves. The system can include a resonator and an acoustic energy harvester located in the resonator. The acoustic energy harvester can be configured to convert acoustic energy into electrical energy. In some instances, the resonator can be a central resonator, and a plurality of surrounding resonators can be arrayed about the central resonator. The surrounding resonators do not include an acoustic energy harvester.

### FIELD

The subject matter described herein relates in general to acoustic resonators and, more particularly, to acoustic energy harvesting using acoustic resonators.

### BACKGROUND

Renewable energy sources can significantly contribute toward the goal of creating clean, inexpensive, and/or sustainable energy. There are a variety of energy sources in an environment, including solar and wind. Another potential energy source is acoustic energy from the ambient environment, which can include noise pollution.

### SUMMARY

In one respect, the present disclosure is directed to an acoustic energy harvesting system. The acoustic energy harvesting system can include a central resonator. The acoustic energy harvesting system can include a plurality of surrounding resonators arrayed about the central resonator. The acoustic energy harvesting system can include an acoustic energy harvester located within the central resonator. The acoustic energy harvester can be configured to convert acoustic energy into electrical energy.

In another respect, the present disclosure is directed to an acoustic energy harvesting system. The acoustic energy harvesting system can include a central resonator. The acoustic energy harvesting system can include an acoustic energy harvester located within the central resonator. The acoustic energy harvester can be configured to convert acoustic energy into electrical energy. The acoustic energy harvesting system can include a plurality of surrounding resonators arrayed about the central resonator. The plurality of surrounding resonators can be substantially equally spaced from the central resonator. The plurality of surrounding resonators can be lossless resonators. The plurality of surrounding resonators do not include an acoustic energy harvester.

### BRIEF DESCRIPTION OF THE DRAWINGS

FIG. 1A is an example of an acoustic energy harvesting arrangement using a single acoustic resonator.

FIG. 1B is an example of an acoustic energy harvesting arrangement using a plurality of acoustic resonators.

FIG. 2A is a first example of an acoustic resonator configured for acoustic energy harvesting.

FIG. 2B is a second example of an acoustic resonator configured for acoustic energy harvesting.

FIG. 2C is a third example of an acoustic resonator configured for acoustic energy harvesting.

FIG. 2D is a fourth example of an acoustic resonator configured for acoustic energy harvesting.

FIG. 2E is a fifth example of an acoustic resonator configured for acoustic energy harvesting.

FIG. 3A is a view of a wall incorporating an acoustic resonator arrangement configured for acoustic energy harvesting.

FIG. 3B is another view of the wall of FIG. 3A.

FIG. 4 is an example of an acoustic energy harvesting system.

FIG. 5A is an example of a pressure amplitude versus frequency graph, showing the difference in performance between the acoustic energy harvesting arrangements of FIGS. 1A and 1B.

FIG. 5B is an example of a pressure amplitude versus frequency graph, showing the difference in performance based on the distance between a central resonator and a plurality of surrounding resonators.

FIG. 6 is an example of a pressure amplitude versus frequency graph, showing the difference in performance based on the distance between a central resonator and a plurality of surrounding resonators.

### DETAILED DESCRIPTION

Resonators can be used in the harvesting of acoustic energy. The resonators typically used in conventional acoustic energy harvesting have a low amplification ratio. For high acoustic energy amplification, focusing of sound is a common approach, requiring a large-sized structure for sound focusing. However, by limiting the number of resonators while realizing large amplification, acoustic energy harvesting can be affordable.

According to arrangements described herein are directed to an effective way to amplify the sound waves for acoustic energy harvesting. Arrangements described herein can limit the number of resonators while realizing large amplification. As a result, arrangements described herein can achieve an affordable acoustic energy harvester.

An acoustic energy harvesting system according to arrangements described herein can include a central resonator. The acoustic energy harvesting system can include a plurality of surrounding resonators arrayed about the central resonator. The acoustic energy harvesting system can include an acoustic energy harvester located in the central resonator. The acoustic energy harvester can be configured to convert acoustic energy into electrical energy.

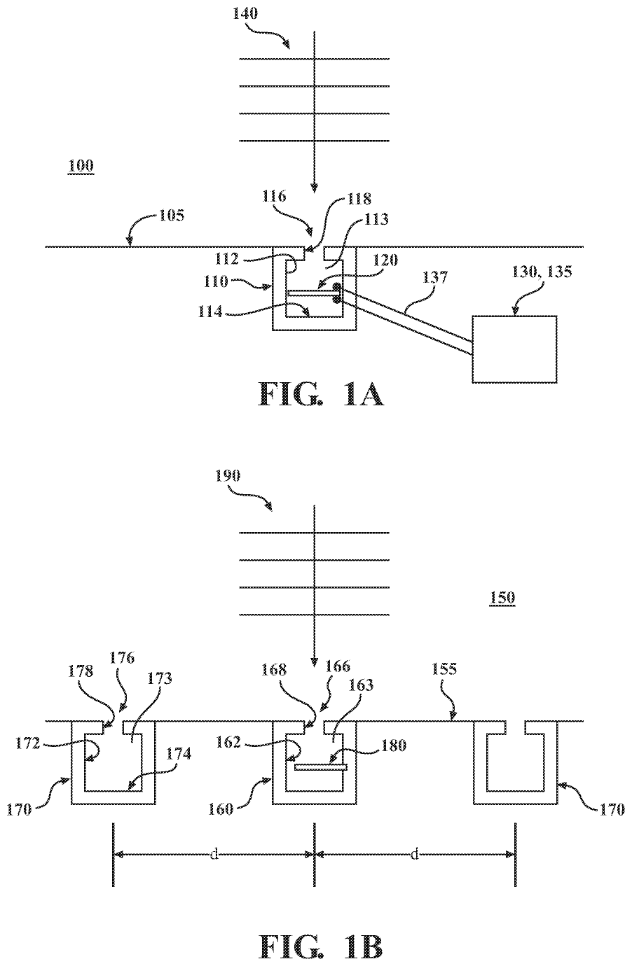

Detailed embodiments are disclosed herein; however, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-6, but the embodiments are not limited to the illustrated structure or application.

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details.

Referring to FIG. 1A, a first example of an acoustic energy harvesting arrangement 100 is shown. The acoustic energy harvesting arrangement 100 can include a resonator 110, which can be an acoustic resonator. The resonator 110 can be defined in a base structure 105. The base structure 105 can be made of any suitable material. The base structure 105 can have any suitable size, shape, and/or configuration. The base structure 105 can be acoustically rigid. But, in some cases, the base structure 105 can be acoustically transparent or flexible as well.

In this example, the resonator 110 can be the only resonator in the acoustic energy harvesting arrangement 100. An acoustic energy harvester 120 can be located within the resonator 110. The acoustic energy harvester 120 can any type of component, device, structure, or system, now known or later developed, configured to convert acoustic energy into electrical energy. The acoustic energy harvester 120 can be any suitable structure. Various examples will be described herein.

The acoustic energy harvester 120 can be operatively connected to another element to which electrical energy can be supplied. For instance, the acoustic energy harvester 120 can be operatively connected to an energy storage device 130 or a device 135 powered by electrical energy. Any suitable form of operative connection can be used, such as by one or more conductors 137 or other carrier or conduit of electrical energy.

The resonator 110 can have any suitable size, shape, and/or configuration. The resonator 110 can be any type of resonator, now known or later developed. The resonator 110 can be a Helmholtz resonator. The resonator 110 can be a lossy resonator. The resonator 110 can have any suitable performance characteristics. The resonator 110 can have a resonance frequency.

The resonator 110 can include at least one sidewall 112. In one or more arrangements, the at least one sidewall 112 can be substantially cylindrical in shape, but other shapes (e.g., rectangular, polygonal, spherical, etc.) are possible. The at least one sidewall 112 can define a cavity 113 having a volume. The resonator 110 can include a distal wall 114. The term “distal” is used for convenience to indicate the location of the wall relative to an inlet end 116 of the resonator 110 and/or the location of the wall relative to an incoming sound wave with respect to the orientation of the resonator 110 shown in FIG. 1A. It will be appreciated that this term is not intended to be limiting. In some arrangements, the resonator 110 can have a neck 118. The neck 118 can be oriented substantially perpendicular to the desired direction of an incident acoustic wave 140.

Turning to FIG. 1B, a second example of an acoustic energy harvesting arrangement 150 is shown. In this arrangement, there can be a plurality of resonators. The plurality of resonators can include a central resonator 160 and a plurality of surrounding resonators 170. The central resonator 160 and the plurality of surrounding resonators 170 can be defined in a base structure 155. The base structure 155 can be made of any suitable material. The base structure 155 can have any suitable size, shape, and/or configuration.

An acoustic energy harvester 180 can be positioned within the central resonator 160. The central resonator 160 can include at least one sidewall 162 that at least partially defines a chamber 163 having a chamber volume. The central resonator 160 can include a distal wall 164 and an inlet end 166. The central resonator 160 can include a neck 168. The discussion of the resonator 110 and the acoustic energy harvester 120 in connection with FIG. 1A applies equally to the central resonator 160 and the acoustic energy harvester 180 of FIG. 1B. While not shown in FIG. 1B, the acoustic energy harvester 180 can be operatively connected to an energy storage device or a device powered by electrical energy. Any suitable form of operative connection can be used, such as by one or more conductors or other carrier or conduit of electrical energy.

The surrounding resonators 170 can be arrayed about the central resonator 160 in any suitable manner. There can be any number of surrounding resonators 170. In this particular example, there can be two surrounding resonators 170. The surrounding resonators 170 can be substantially equally spaced from the central resonator 160 by a distance d. In some arrangements, the distance d can be measured from the center of the central resonator 160 to the center of the surrounding resonator 170. Further, the surrounding resonators 170 can be substantially equally spaced from each other in a circumferential direction about the central resonator 160. The surrounding resonators 170 and the central resonator 160 can be acoustically coupled.

The surrounding resonators 170 can be any type of resonator, now known or later developed. The surrounding resonators 170 can be Helmholtz resonators. The surrounding resonators 170 can be lossless resonators. The surrounding resonators 170 do not have an associated acoustic energy harvester.

The surrounding resonators 170 can have any suitable size, shape, and/or configuration. In some arrangements, the surrounding resonators can be substantially identical to each other. In other arrangements, one or more of the surrounding resonators 170 can be different from the other surrounding resonators 170 in one or more respects, including size, shape, configuration, and/or one or more performance characteristics. In one or more arrangements, the surrounding resonators 170 can be substantially identical to the central resonator 160, such as in terms of size, shape, and/or configuration. In this regard, the above discussion of the resonator 110 can apply equally to the surrounding resonators 170. The surrounding resonators 170 can include at least one sidewall 172, a volume 173, a distal wall 174, an inlet end 176, and/or a neck 178. The neck 178 can be oriented substantially perpendicular to the desired direction of an incident acoustic wave 190.

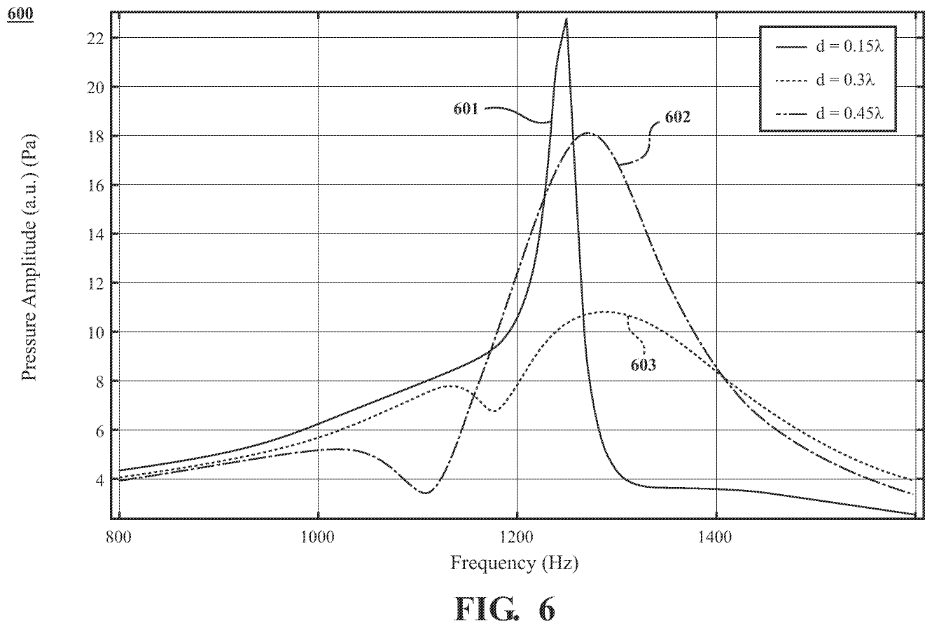

It should be noted that the distance d between the central resonator 160 and the surrounding resonators 170 can affect acoustic performance. Indeed, referring to FIG. 6, a graph 600 of pressure amplitude v. frequency is shown.

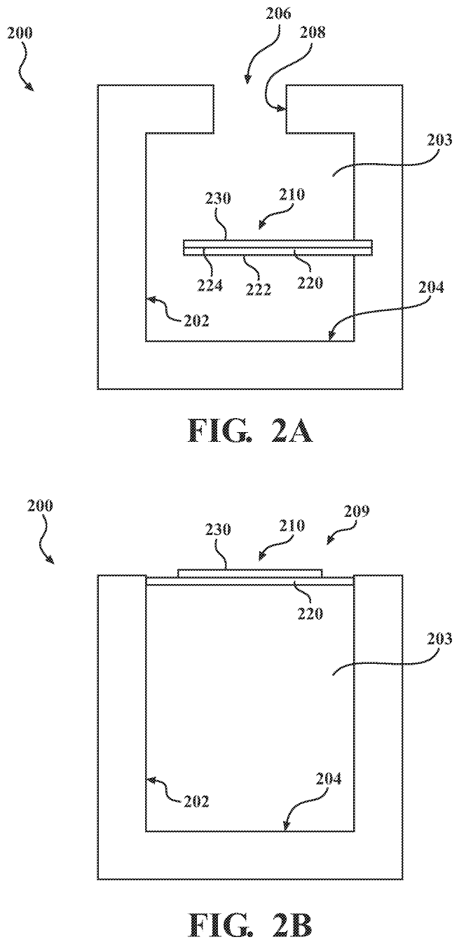

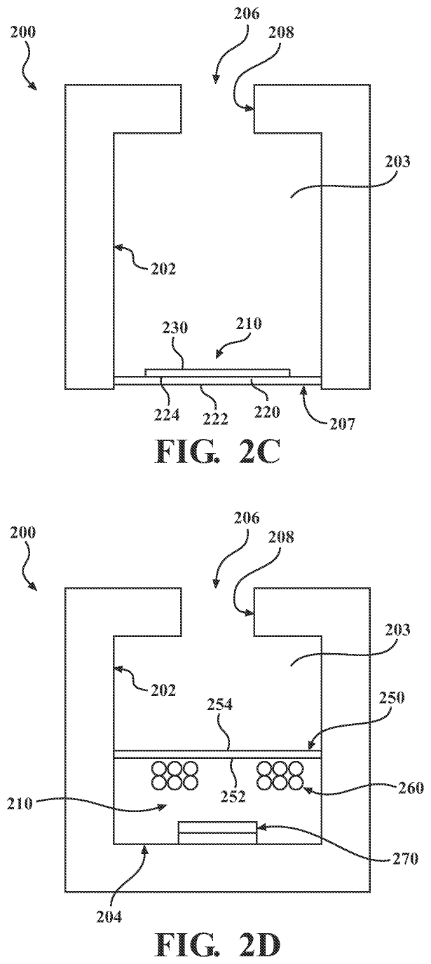

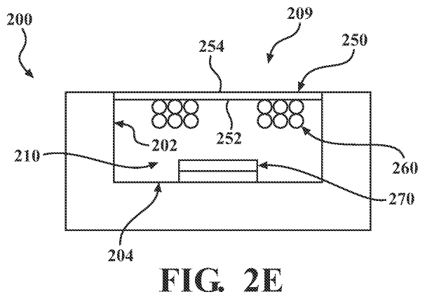

As noted above, an acoustic energy harvester can be used in connection with the resonator 110 and the central resonator 160. There can be various suitable acoustic energy harvesters. FIGS. 2A-2E shows various examples of the acoustic energy harvesters. For convenience and where appropriate, reference numbers are reused throughout these figures.

In some arrangements, the acoustic energy harvester can include a membrane and a piezoelectric patch. There are various ways in which the membrane and the piezoelectric patch can be arranged. Various non-limiting examples of such an acoustic energy harvester will be described in connection with FIGS. 2A-2C.

FIG. 2A is a first example of an acoustic resonator configured for acoustic energy harvesting. A resonator 200 can correspond to the resonator 110 and/or the central resonator 160 described above in connection with FIGS. 1A-1B. The resonator 200 can include at least one sidewall 202, a chamber or a cavity 203, a distal wall 204, an inlet end 206, and a neck 208.

The acoustic energy harvester 210 can include a membrane 220 and a piezoelectric patch 230. The membrane 220 can be made of any suitable material, such as a plastic. In some arrangements, the membrane 220 can be made of a flexible material. In some arrangements, the membrane 220 can be a plate. The membrane 220 can be relatively thin, such as about 0.5 inches or less, about 0.25 inches or less, or about 0.125 inches or less, just to name a few possibilities. In some arrangements, the piezoelectric patch 230 and the membrane 220 can be a pre-assembled unit. In some arrangements, the piezoelectric patch 230 can be substantially centered on the membrane 220. In some arrangements, the piezoelectric patch 230 can have a smaller footprint than the membrane 220. The piezoelectric patch 230 can be any type of piezoelectric patch or piezoelectric transducer, now known or later developed. In some arrangements, the piezoelectric patch 230 can be made of polyvinylidene fluoride (PVDF).

The membrane 220 can be associated with the resonator 200. For instance, the membrane 220 can be located within the cavity 203 of the resonator 200. The membrane 220 can extend from the at least one sidewall 202 of the resonator 200. The membrane 220 can extend cantilevered from the at least one sidewall 202. In some arrangements, the membrane 220 can be partially received in an aperture defined in the at least one sidewall 202. In some arrangements, the membrane 220 can extend at least partially across a width of the cavity 203. In some arrangements, the membrane 220 can extend across a majority of the width of the cavity 203. The membrane 220 can be substantially perpendicular to the at least one sidewall 202. The membrane 220 can be substantially parallel to the distal wall 204 of the resonator 200. The membrane 220 can be operatively connected to the at least one sidewall 202 in any suitable manner, such as by one or more fasteners, one or more adhesives, one or more welds, one or more brazes, one or more forms of mechanical engagement, or any combination thereof, just to name a few possibilities. The membrane 220 can include an outward facing side 222 and an inward facing side 224. The terms “outward” and “inward” are used for convenience to note the position of the side relative to the inlet end 206 of the resonator 200. These terms are not intended to be limiting.

The piezoelectric patch 230 can be located on one side of the membrane 220. For instance, the piezoelectric patch 230 can be located on the outward facing side 222 of the membrane 220. The piezoelectric patch 230 can be any type of piezoelectric patch, now known or later developed. The piezoelectric patch 230 can be operatively connected to the membrane 220. For instance, the piezoelectric patch 230 can be operatively connected to the membrane 220 by one or more adhesives, one or more fasteners, one or more forms of mechanical engagement, one or more other forms of connection, or any combination thereof. The piezoelectric patch 230 can be operatively connected to the at least one sidewall 202 in any suitable manner, such as by one or more fasteners, one or more adhesives, one or more welds, one or more brazes, one or more forms of mechanical engagement, or other form of connection, or any combination thereof, just to name a few possibilities.

The membrane 220 backed by an air chamber can function as an acoustic resonator for energy harvesting. In response to amplified sound within the resonator 200, the membrane 220 and the piezoelectric patch 230 can be oscillated. As a result, the acoustic energy can be converted to electrical energy.

FIG. 2B is a second example of an acoustic resonator configured for acoustic energy harvesting. The acoustic energy harvester 210 can include a membrane 220 and a piezoelectric patch 230. The above discussion of the membrane 220 and the piezoelectric patch 230 apply equally here. The piezoelectric patch 230 can be located on the outward facing side 222 of the membrane 220. In this example, the membrane 220 and the piezoelectric patch 230 can be located at a proximal end 209 of the resonator 200. The term “proximal” is used here for convenience to indicate a relative location of a portion of the resonator 200 with respect to an incoming sound wave when the resonator 200 is in the orientation shown in FIG. 2B. The term “proximal” is not intended to be limiting. The membrane 220 and the piezoelectric patch 230 can close the proximal end 209 of the resonator 200. The acoustic energy harvester 210 can at least partially define the proximal end 209 of the resonator 200. The membrane 220 can be operatively connected on opposite portions of the at least one sidewall 202 in any suitable manner, such as by one or more fasteners, one or more adhesives, one or more welds, one or more brazes, one or more forms of mechanical engagement, one or more other forms of connection, or any combination thereof, just to name a few possibilities.

FIG. 2C is a third example of an acoustic resonator configured for acoustic energy harvesting. The acoustic energy harvester 210 can include a membrane 220 and a piezoelectric patch 230. The above discussion of the membrane 220 and the piezoelectric patch 230 apply equally here. The piezoelectric patch 230 can be located on the inward facing side 224 of the membrane 220. In this example, the membrane 220 and the piezoelectric patch 230 can be located at or near a distal end 207 of the resonator 200. The term “distal” is used here for convenience to indicate a location of a portion of the resonator 200 relative to an incoming sound wave when in the orientation shown in FIG. 2C. The term “distal” is not intended to be limiting. The membrane 220 and the piezoelectric patch 230 can close the distal end 207 of the resonator 200. The acoustic energy harvester 210 can at least partially define the distal end 207 of the resonator 200. The membrane 220 can be operatively connected on opposite portions of the at least one sidewall 202 in any suitable manner, such as by one or more fasteners, one or more adhesives, one or more welds, one or more brazes, one or more forms of mechanical engagement, one or more other forms of connection, or any combination thereof, just to name a few possibilities.

In some arrangements, the acoustic energy harvester 210 can be configured to induce a current using, for example, a coil and a magnet. There are various ways in which the coil and the magnet can be arranged. Various non-limiting examples will be described in connection with FIGS. 2D-2E.

FIG. 2D is a fourth example of an acoustic resonator configured for acoustic energy harvesting. An acoustic energy harvester 210 can be associated with the resonator 200. The acoustic energy harvester 210 can include a membrane 250, a coil 260, and a magnet 270. The above discussion of the membrane 220 applies equally to the membrane 250.

The membrane 250 can be associated with the resonator 200. For instance, the membrane 250 can be located within the cavity 203 of the resonator 200. The membrane 250 can extend cantilevered from the at least one sidewall 202. In some arrangements, the membrane 250 can be partially received in an aperture defined in the at least one sidewall 202. In some arrangements, the membrane 250 can extend at least partially across a width of the cavity 203. In some arrangements, the membrane 250 can extend across a majority of the width of the cavity 203. The membrane 250 can be substantially perpendicular to the at least one sidewall 202. The membrane 250 can be substantially parallel to the distal wall 204 of the resonator 200. The membrane 250 can be operatively connected to the at least one sidewall 202 in any suitable manner, such as by one or more fasteners, one or more adhesives, one or more welds, one or more brazes, one or more forms of mechanical engagement, or any combination thereof, just to name a few possibilities. The membrane 250 can include an outward facing side 254 and an inward facing side 252. The terms “outward” and “inward” are used for convenience to note the relationship of the side relative to the inlet end 206 of the resonator 200. These terms are not intended to be limiting.

The coil 260 can be operatively positioned substantially adjacent to one side of the membrane 250. For instance, the coil 260 can be operatively positioned substantially adjacent to the inward facing side 252 of the membrane 250. “Substantially adjacent” includes direct contact and slight spacings of about 3 inches or less, about 2 inches or less, about 1 inch or less, 0.5 inches or less, or 0.25 inches or less. The coil 260 can be any type of coil, now known or later developed. The coil 260 can be made of any suitable material, including, for example, copper. The coil 260 can be operatively connected to the membrane 250 in any suitable manner. For instance, the coil 260 can be operatively connected to the membrane 250 by one or more fasteners, one or more adhesives, one or more welds, one or more brazes, one or more forms of mechanical engagement, one or more other forms of connection, or any combination thereof, just to name a few possibilities. The coil 260 can be substantially centrally located on the membrane 250.

The magnet 270 can be a permanent magnet. The magnet 270 can be located within the cavity 203. The magnet 270 can be spaced from the coil 260. In some arrangements, the magnet 270 can be substantially aligned with the coil 260, such as shown in FIG. 2D. In some arrangements, the magnet 270 can be supported on the distal wall 204 of the cavity 203. In some arrangements, the magnet 270 can be operatively connected to the distal wall 204 in any suitable manner, such as by one or more fasteners, one or more adhesives, one or more welds, one or more brazes, one or more forms of mechanical engagement, one or more other forms of connection, or any combination thereof, just to name a few possibilities. In some arrangements, the magnet 270 can be fixed in its location.

In response to amplified sound within the resonator 200, the membrane 250 and the coil 260 can be oscillated. The coil 260, when oscillating relative to the magnet 270, can induce current for energy harvesting. In this way, the acoustic energy from an incoming sound wave can be converted to electrical energy.

FIG. 2E is a fifth example of an acoustic resonator configured for acoustic energy harvesting. An acoustic energy harvester 210 can be associated with the resonator 200. The acoustic energy harvester 210 can include a membrane 250, a coil 260, and a magnet 270. The above discussion of the membrane 220 can apply equally to the membrane 250. The above discussion of the coil 260 and the magnet 270 in connection with FIG. 2D can apply equally here.

In this example, the membrane 250 and the coil 260 can be located at a proximal end 209 of the resonator 200. The term “proximal” is used here for convenience to indicate a relative location of a portion of the resonator 200 relative to an incoming sound wave when the resonator 200 is in the orientation shown in FIG. 2E. The term “proximal” is not intended to be limiting. The membrane 250 and the coil 260 can close the proximal end 209 of the resonator 200. The acoustic energy harvester 210 can at least partially define the proximal end 209 of the resonator 200. The membrane 250 can be operatively connected on opposite portions of the at least one sidewall 202 in any suitable manner, such as by one or more fasteners, one or more adhesives, one or more welds, one or more brazes, one or more forms of mechanical engagement, one or more other forms of connection, or any combination thereof, just to name a few possibilities. The coil 260 can be operatively positioned substantially adjacent to one side of the membrane 250. For instance, the coil 260 can be operatively positioned substantially adjacent to the inward facing side 252 of the membrane 250. In this example, the resonator 200 may or may not have a neck.

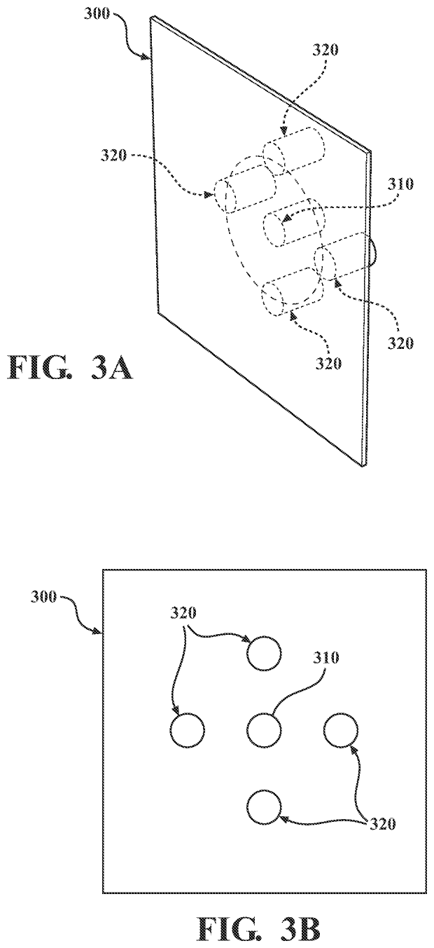

The arrangements described herein can be used in various applications. For instance, referring to FIGS. 3A-3B, the arrangements described herein can be incorporated into a wall or a panel 300. In this example, there can be the central resonator 310 and a plurality of surrounding resonators 320. The surrounding resonators 320 can be arrayed about the central resonator 310 in any suitable manner. An acoustic energy harvester 330 can be positioned within the central resonator 310. It will be appreciated that the above discussion of the resonators 110, 200, the central resonator 160, the surrounding resonators 170, and the acoustic energy harvesters 120, 210 apply equally to the central resonator 310, the surrounding resonators 320, and the acoustic energy harvesters 330.

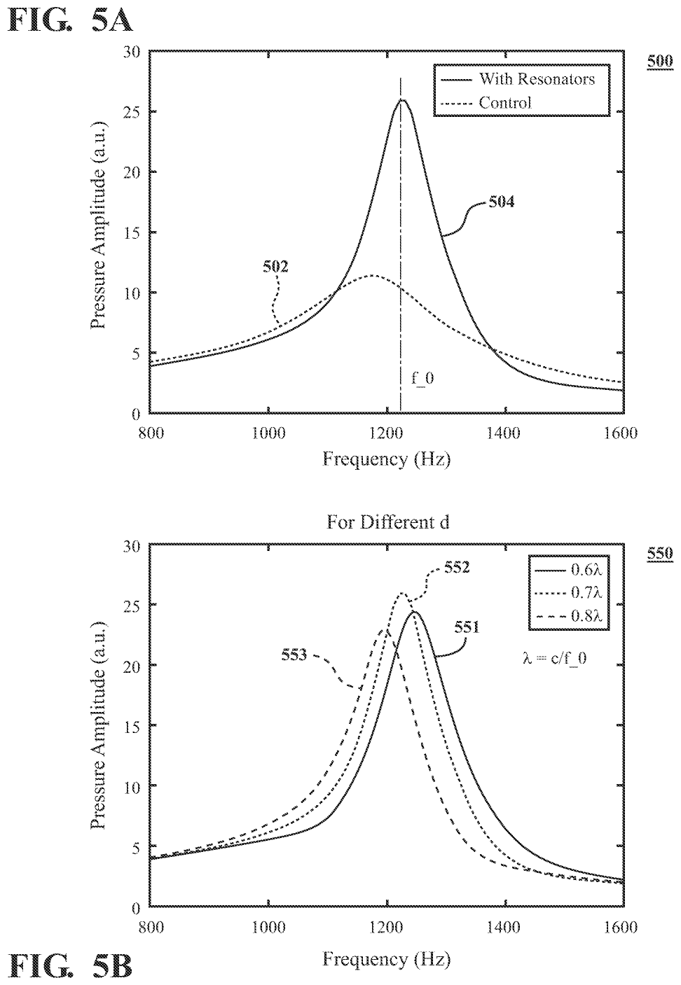

Some examples of the performance of the system will now be described. FIGS. 5A and 5B show an example of pressure amplitude spectra characterized inside the resonator. FIG. 5A is an example of a graph 500 of pressure amplitude versus frequency. The graph 500 shows two curves. A first curve 502 represents the FIG. 1A arrangement in which there is a single resonator with an acoustic energy harvester. A second curve 504 represents the FIG. 1B arrangement in which there is a central resonator with an acoustic energy harvester with a plurality of surrounding resonators arrayed about the central resonator. As is evident, the pressure amplitude is maximized around the resonance frequency (f_0).

FIG. 5B is an example of a graph 550 of pressure amplitude versus frequency for the FIG. 1B arrangement. This graph 550 shows the effect of different distances on performance of the resonator. The graph 550 includes three curves, each representing the surrounding resonators 170 at different distances from the central resonator 160. A first curve 551 represents the surrounding resonators 170 spaced from the central resonator 160 at a distance d of 0.6λ. A second curve 552 represents the surrounding resonators 170 spaced from the central resonator 160 at a distance d of 0.7λ. A third curve 553 represents the surrounding resonators 170 spaced from the central resonator 160 at a distance d of 0.8λ. As shown in FIG. 5B, the distance (d) between the central resonator 160 and the surrounding resonators 170 influences the sound amplification, enabling optimized performance for d=0.7λ with λ being the wavelength at f_0.

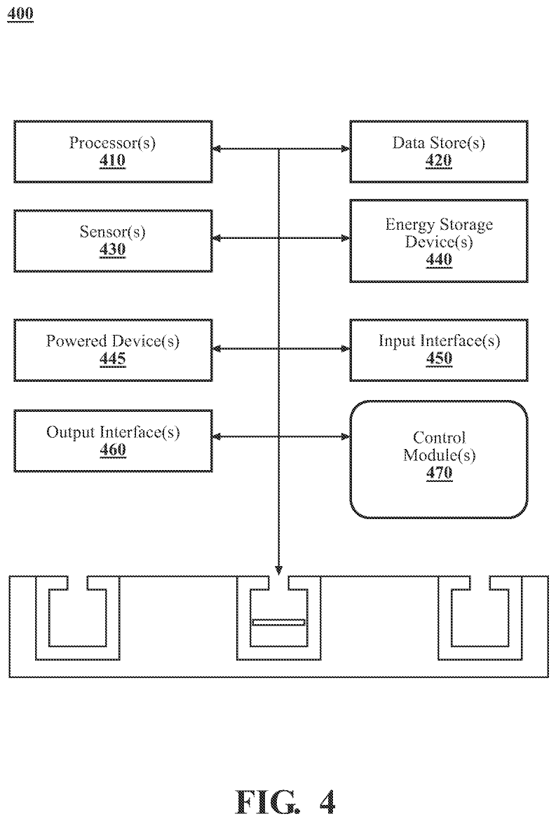

FIG. 4 shows an example of a system 400. The system 400 can include various elements. Some of the possible elements of the system 400 are shown in FIG. 4 and will now be described. It will be understood that it is not necessary for the system 400 to have all of the elements shown in FIG. 4 or described herein. The system 400 can have any combination of the various elements shown in FIG. 4. Further, the system 400 can have additional elements to those shown in FIG. 4. In some arrangements, the system 400 may not include one or more of the elements shown in FIG. 4. Further, the elements shown may be physically separated by large distances. Indeed, one or more of the elements can be located remote from the other elements of the system 400. The system 400 can be used in connection with an acoustic energy harvesting arrangement, including, for example, those shown in FIGS. 1A-1B, FIGS. 2A-2E, and/or FIGS. 3A-3B.

The system 400 can include one or more processors 410, one or more data stores 420, one or more sensors 430, one or more energy storage devices 440, one or more powered devices 445, one or more input interfaces 450, one or more output interfaces 460, and one or more control modules 470.

The energy storage device(s) 440 can be any component or group of components capable of receiving and/or storing electrical energy for later consumption. In one embodiment, the energy storage device(s) 440 can include batteries, rechargeable batteries, capacitors, and/or supercapacitors. In one or more arrangements, the energy storage device(s) 440 can be configured to receive and store electrical energy received from the acoustic energy harvester(s) 120, 210, 330 described herein.

The system 400 can include one or more powered devices 445. “Powered device” means any device that is at least partially powered by electrical energy. The powered device(s) 445 can receive electrical energy from the acoustic energy harvester(s) 120, 210, 330 described herein. Alternatively or additionally, the powered device(s) 445 can receive electrical energy from the energy storage device(s) 440.

The system 400 can include one or more modules, at least some of which will be described herein. The modules can be implemented as computer readable program code that, when executed by a processor, implement one or more of the various processes described herein. One or more of the modules can be a component of the processor(s) 410, or one or more of the modules can be executed on and/or distributed among other processing systems to which the processor(s) 410 is operatively connected. The modules can include instructions (e.g., program logic) executable by one or more processor(s) 410. Alternatively or in addition, one or more data stores 420 may contain such instructions. In one or more arrangements, the modules described herein can include artificial or computational intelligence elements, e.g., neural network, fuzzy logic, or other machine learning algorithms. Further, in one or more arrangements, the modules can be distributed among a plurality of modules.

The system 400 can include one or more control modules 470. The control module(s) 470 can be configured to receive signals, data, information, and/or other inputs from one or more elements of the system 400, such as the sensor(s) and/or the input interface(s) 450. The control module(s) 470 can be configured to analyze these signals, data, information, and/or other inputs. The control module(s) 470 can be configured to cause electrical energy from the acoustic energy harvesters to be supplied to the energy storage device(s) 440 and/or the powered device(s) 445. Alternatively or additionally, the control module(s) 470 can be configured to detect user inputs (e.g., commands) provided on the input interface(s) 450. The control module(s) 470 can be configured to send control signals or commands over a communication network 490 to one or more elements of the system 400. The control module(s) 470 can selectively permit or prevent the flow of electrical energy from the energy storage device(s) 440 and/or the powered device(s) 445.

The various elements of the system 400 can be communicatively linked to one another or one or more other elements through one or more communication networks 490. As used herein, the term “communicatively linked” can include direct or indirect connections through a communication channel, bus, pathway or another component or system. A “communication network” means one or more components designed to transmit and/or receive information from one source to another. The data store(s) 420 and/or one or more other elements of the system 400 can include and/or execute suitable communication software, which enables the various elements to communicate with each other through the communication network and perform the functions disclosed herein.

Arrangements described herein can be used in a variety of settings and applications. A non-limiting example of the use of the arrangements described herein will now be presented in connection to FIGS. 3A-3B. In this example, the arrangements described herein can be used in connection a wall. The wall can be a wall of any structure, including indoor structures or outdoor structures. In some arrangements, the wall can be part of a vehicle, a dwelling, or a place of business. In FIGS. 3A-3B, the central resonator can contain a sound-to-electricity converter. The central resonator can be surrounded by four surrounding resonators. The four surrounding resonators can be substantially equally spaced from the central resonator. The four surrounding resonators can be substantially equally spaced from each other.

It will be appreciated that arrangements described herein can provide numerous benefits, including one or more of the benefits mentioned herein. For example, arrangements described herein can provide an effective way to amplify the sound waves for acoustic energy harvesting. Arrangements described herein can limit the number of resonators while realizing large amplification. Arrangements described herein can achieve an affordable acoustic energy harvester.

The flowcharts and block diagrams in the figures illustrate the architecture, functionality, and operation of possible implementations of systems, methods and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or other apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises all the features enabling the implementation of the methods described herein and which, when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk drive (HDD), a solid state drive (SSD), a random access memory (RAM), a read-only memory (ROM), an erasable programmable read-only memory (EPROM or Flash memory), an optical fiber, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain or store a program for use by or in connection with an instruction execution system, apparatus, or device.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e. open language). The term “or” is intended to mean an inclusive “or” rather than an exclusive “or.” The phrase “at least one of . . . and . . . ” as used herein refers to and encompasses any and all possible combinations of one or more of the associated listed items. As an example, the phrase “at least one of A, B and C” includes A only, B only, C only, or any combination thereof (e.g. AB, AC, BC or ABC). As used herein, the term “substantially” or “about” includes exactly the term it modifies and slight variations therefrom. Thus, the term “substantially parallel” means exactly parallel and slight variations therefrom. “Slight variations therefrom” can include within 15 degrees/percent/units or less, within 14 degrees/percent/units or less, within 13 degrees/percent/units or less, within 12 degrees/percent/units or less, within 11 degrees/percent/units or less, within 10 degrees/percent/units or less, within 9 degrees/percent/units or less, within 8 degrees/percent/units or less, within 7 degrees/percent/units or less, within 6 degrees/percent/units or less, within 5 degrees/percent/units or less, within 4 degrees/percent/units or less, within 3 degrees/percent/units or less, within 2 degrees/percent/units or less, or within 1 degree/percent/unit or less. In some instances, “substantially” can include being within normal manufacturing tolerances.

Aspects herein can be embodied in other forms without departing from the spirit or essential attributes thereof. Accordingly, reference should be made to the following claims, rather than to the foregoing specification, as indicating the scope hereof.

What is claimed is:

1. An energy harvesting system comprising:
a central resonator;
a plurality of surrounding resonators arrayed about the central resonator; and
an acoustic energy harvester located in the central resonator, the acoustic energy harvester being configured to convert acoustic energy into electrical energy.

2. The energy harvesting system of claim 1, wherein the central resonator is a Helmholtz resonator.

3. The energy harvesting system of claim 1, wherein the plurality of surrounding resonators are substantially equally spaced from the central resonator.

4. The energy harvesting system of claim 1, wherein a center-to-center distance between the central resonator and the plurality of surrounding resonators is about 0.7λ, wherein λ is a wavelength of an incident acoustic wave at a resonance frequency of the central resonator.

5. The energy harvesting system of claim 1, wherein the plurality of surrounding resonators are lossless resonators.

6. The energy harvesting system of claim 1, further including an energy storage device, wherein the energy storage device is operatively connected to receive electrical energy from the acoustic energy harvester.

7. The energy harvesting system of claim 1, further including a device, wherein the device is powered by electrical energy, and wherein the device is operatively connected to receive electrical energy from the acoustic energy harvester.

8. The energy harvesting system of claim 1, wherein the acoustic energy harvester includes a piezoelectric patch operatively connected to a membrane.

9. The energy harvesting system of claim 8, wherein the piezoelectric patch and the membrane extend cantilevered from a side wall of the central resonator.

10. The energy harvesting system of claim 8, wherein the piezoelectric patch and the membrane are located at an upper end of the central resonator, whereby the piezoelectric patch and the membrane at least partially define the upper end of the central resonator.

11. The energy harvesting system of claim 8, wherein the piezoelectric patch and the membrane are located at a lower end of the central resonator, whereby the piezoelectric patch and the membrane at least partially define the lower end of the central resonator.

12. The energy harvesting system of claim 1, wherein the acoustic energy harvester includes a membrane and a coil operatively positioned substantially adjacent to the membrane, and wherein the acoustic energy harvester includes a permanent magnet.

13. An energy harvesting system comprising:
a central resonator;
an acoustic energy harvester located in the central resonator, the acoustic energy harvester being configured to convert acoustic energy into electrical energy; and
a plurality of surrounding resonators arrayed about the central resonator, the plurality of surrounding resonators being substantially equally spaced from the central resonator, the plurality of surrounding resonators being lossless resonators, the plurality of surrounding resonators do not include an acoustic energy harvester.

14. The energy harvesting system of claim 13, wherein the central resonator is a Helmholtz resonator.

15. The energy harvesting system of claim 13, wherein a center-to-center distance between the central resonator and the plurality of surrounding resonators is about 0.7λ, wherein λ is a wavelength of an incident acoustic wave at a resonance frequency of the central resonator.

16. The energy harvesting system of claim 13, wherein the central resonator and the plurality of surrounding resonators are defined in a wall or a panel.

17. The energy harvesting system of claim 13, further including an energy storage device, wherein the energy storage device is operatively connected to receive electrical energy from the acoustic energy harvester.

18. The energy harvesting system of claim 13, further including a device, wherein the device is powered by electrical energy, and wherein the device is operatively connected to receive electrical energy from the acoustic energy harvester.

19. The energy harvesting system of claim 13, wherein the acoustic energy harvester includes a piezoelectric patch operatively connected to a membrane.

20. The energy harvesting system of claim 13, wherein the acoustic energy harvester includes a membrane and a coil operatively positioned substantially adjacent to the membrane, and wherein the acoustic energy harvester includes a permanent magnet.
